(19) United States
(12) Patent Application Publication
(10) Pub. No.: US 2026/0271327 A1
(43) Pub. Date: Sep. 10, 2026

(54) RECESSED P-TYPE GATE STRUCTURE FOR III-NITRIDE TRANSISTORS

(71) Applicant: Bin Lu, Fremont, CA (US)

(72) Inventor: Bin Lu, Fremont, CA (US)

(21) Appl. No.: 19/555,383

(22) Filed: Mar. 3, 2026

Related U.S. Application Data
(60) Provisional application No. 63/767,538, filed on Mar. 5, 2025.

(51) Int. Cl. H10D 30/47; H10D 30/01; H10D 62/10; H10D 62/60; H10D 62/824

(52) U.S. Cl. CPC H10D 30/475; H10D 30/015; H10D 62/102; H10D 62/60; H10D 62/824

(57) ABSTRACT

A III-nitride transistor device includes a recessed p-type gate structure in which a cap layer shields the underlying channel from process-induced surface damage in the access regions, and an etch stop layer enables uniform and controlled gate recess etching. The device comprises, sequentially over a substrate: a buffer layer, a III-nitride channel layer, an etch stop layer selected from AlN, AlGaN, InAlN, or combinations thereof, a III-nitride cap layer recessed in the gate region to expose the etch stop layer, a barrier layer formed over the exposed etch stop layer in the gate recess, a Mg-doped p-type III-nitride layer over the barrier layer, and a gate electrode. Source and drain electrodes are formed on opposing sides of the gate, optionally in ohmic recess regions extending to a controlled depth within the layer stack. The device may be operated in enhancement or depletion mode depending on layer composition and thickness.

### CROSS-REFERENCE TO RELATED APPLICATIONS

This application claims the benefit of priority to U.S. Provisional Patent Application No. 63/767,538, filed on Mar. 5, 2025, entitled “Recessed P-Type Gate Structure with an Etch Stop Layer,” the entire contents of which are incorporated herein by reference.

### BACKGROUND OF THE INVENTION

### Field of the Invention

The present invention relates to semiconductor devices, and more particularly to III-nitride based high-electron-mobility transistors (HEMTs) incorporating a recessed p-type gate structure with an etch stop layer and a cap layer to improve gate recess etch uniformity, mitigate process-induced surface damage in the access regions, and enhance device reliability.

### Description of Related Art

Gallium nitride (GaN)-based high-electron-mobility transistors (HEMTs) are widely employed in power electronics applications due to their wide bandgap, high critical electric field, high electron mobility, and high saturation velocity. For power switching applications, normally-off operation is essential for fail-safe behavior and simplified gate-driver circuitry. One well-established approach to achieving normally-off operation employs a p-type GaN (pGaN) layer beneath the gate electrode, which depletes the two-dimensional electron gas (2 DEG) channel beneath the gate and yields a positive threshold voltage.

Despite the commercial success of pGaN gate transistors, the conventional pGaN gate structure suffers from three fundamental limitations that have resisted simultaneous resolution.

First, in conventional pGaN gate structures, the AlGaN barrier layer is continuous and uniform across both the gate region and the access regions between the gate and the source and drain contacts. Because the barrier thickness and aluminum composition in the access regions are identical to those in the gate region, the 2 DEG density in the access regions and the gate threshold voltage are inextricably coupled. Increasing the barrier aluminum content or thickness to raise access region 2 DEG density and reduce on-resistance simultaneously weakens the depletion effect of the pGaN gate and lowers the threshold voltage. Conversely, reducing the barrier aluminum content or thickness to raise the threshold voltage necessarily reduces the access region 2 DEG density and increases on-resistance. This trade-off represents an intrinsic design constraint of conventional pGaN gate structures.

Second, defining the pGaN gate region requires removal of the pGaN layer from the access regions by dry etching, typically using inductively coupled plasma reactive ion etching (ICP-RIE). Upon completion of pGaN removal, the dry etch contacts and damages the AlGaN barrier surface in the access regions (e.g., surface damage 165 shown in FIG. 1), introducing surface defects that act as electron trapping centers during high-voltage operation. Electron trapping causes current collapse and dynamic on-resistance degradation, contributing to device instability and long-term reliability concerns. Furthermore, precise control of the residual AlGaN thickness is technically challenging, resulting in device-to-device and wafer-to-wafer variability in on-resistance uniformity.

Third, the formation of low-resistance ohmic contacts to the 2 DEG channel presents additional process control challenges. When ohmic recess etching into the AlGaN barrier is employed, the absence of a self-limiting etch stop results in poor recess depth control, translating directly into variability in contact resistance and on-resistance across the wafer.

The Through Recessed and Regrowth Gate (TRRG) technology of Okita et al. addresses the threshold voltage uniformity problem by fully removing the AlGaN barrier in the gate region and epitaxially regrowing it, such that the regrown AlGaN thickness independently determines the threshold voltage without constraining the access region barrier. However, the TRRG process performs gate recess by non-selective timed dry etching through the entire AlGaN barrier into the GaN channel without a defined etch stop, introducing surface roughness and crystal damage at the channel interface underlying the regrown barrier. The TRRG structure also provides no etch stop for ohmic contact formation, leaving ohmic recess depth subject to the same timed etch variability as conventional structures. Furthermore, the original AlGaN barrier in the access region is exposed to photoresist processing during gate recess patterning and to elevated temperatures during epitaxial regrowth, both of which can degrade the original barrier surface quality. Subsequent removal of the regrown pGaN layer from the access regions by dry etching further damages the underlying regrown AlGaN barrier surface, reintroducing the same plasma-induced surface defects and electron trapping mechanisms that afflict conventional pGaN gate structures.

A structurally distinct approach to normally-off operation without using pGaN in the gate region is the recessed-gate transistor. Lu et al. demonstrated that an etch stop layer positioned beneath a GaN cap layer enables selective cap removal with self-termination, yielding precise and uniform gate recess depth and reduced plasma damage. However, this structure employs a deposited gate dielectric on the recessed surface, forming a metal-insulator-semiconductor FET (MISFET) architecture rather than a p-type gate structure. Gate dielectric-based enhancement-mode transistors introduce reliability challenges of their own, including threshold voltage instability from charge trapping at the gate dielectric interface, which has been a persistent obstacle to commercialization of GaN MISFETs in high-reliability applications.

The etch stop approach of Lu et al. and the barrier regrowth approach of Okita et al. each address a subset of the foregoing limitations but neither addresses all of them within a single device architecture. Accordingly, there remains a need for an improved III-nitride transistor structure incorporating a p-type gate that overcomes these limitations in a unified and manufacturable process.

### BRIEF SUMMARY OF THE INVENTION

The present invention provides a III-nitride transistor device comprising a recessed p-type gate structure in which a cap layer shields the access regions from process-induced surface damage, an etch stop layer enables uniform and controlled gate recess etching, and the combination decouples the gate threshold voltage from the access region resistance within a single unified device architecture. The invention also provides a method of fabricating such a transistor device.

In one aspect, a transistor device is provided comprising: a substrate; a buffer layer over the substrate; a channel layer comprising a III-nitride semiconductor over the buffer layer; an etch stop layer over the channel layer; a cap layer over the etch stop layer, the cap layer having a recessed gate region in which the cap layer is removed to expose the etch stop layer; a barrier layer formed at least in the recessed gate region over the etch stop layer; a p-type III-nitride layer formed at least in the recessed gate region over the barrier layer; a gate electrode over the p-type III-nitride layer; and source and drain electrodes on opposing lateral sides of the gate electrode. The cap layer protects the underlying etch stop layer and 2 DEG channel from process-induced surface damage in the access regions. In certain embodiments, the cap layer is n-type doped, providing a lateral conduction path in parallel with the 2 DEG channel, reducing access region resistance, and enabling low-resistance ohmic contact formation.

The barrier layer and p-type III-nitride layer may extend laterally beyond the recessed gate region onto at least a portion of the access regions. In one embodiment, the lateral edges of the barrier layer and the p-type III-nitride layer are substantially aligned with each other. In another embodiment, the barrier layer extends laterally further into the access regions than the p-type III-nitride layer.

The source and drain electrodes may be formed in ohmic recess regions extending to a selected depth within the layer stack, including partially into or through the barrier layer, partially into or through the cap layer, partially into or through the etch stop layer, or into the channel layer. In certain embodiments, a heavily doped n-type III-nitride region is formed in the ohmic recess regions underneath the source and drain electrodes.

In another aspect, a method of fabricating such a transistor device is provided, comprising forming each of the foregoing layers sequentially, selectively removing the cap layer in the gate region to expose the etch stop layer, forming the barrier layer and p-type III-nitride layer at least in the recessed gate region, selectively removing the p-type III-nitride layer from at least a portion of the access regions, wherein the barrier layer may be removed contemporaneously with or independently from the removal of the p-type III-nitride layer, forming ohmic recess regions at the source and drain electrode locations, and forming the gate and source/drain electrodes.

### BRIEF DESCRIPTION OF THE DRAWINGS

FIG. 1 is a cross-sectional view of a conventional GaN transistor with a pGaN gate over an AlGaN barrier, illustrating etch damage 165 at the barrier surface in the access regions (Prior Art).

FIG. 2 is a cross-sectional view of a transistor device according to a first embodiment of the invention, showing a recessed cap layer, an etch stop layer, a barrier layer, and a p-type III-nitride gate structure, wherein the lateral edges of the barrier layer and the p-type III-nitride layer are substantially aligned with each other and extend beyond the recessed gate region, with the cap layer exposed in a portion of the access regions.

FIG. 3 is a cross-sectional view of a transistor device according to a second embodiment, wherein the barrier layer extends laterally further into the access regions than the p-type III-nitride layer, and the source and drain electrodes are formed in ohmic recess regions extending into the cap layer.

FIG. 4 is a cross-sectional view of a transistor device according to a third embodiment, wherein the lateral edges of the barrier layer and the p-type III-nitride layer are substantially aligned with the edges of the recessed gate region.

FIG. 5 is a cross-sectional view of a transistor device according to a fourth embodiment, wherein the cap layer is n-type doped.

FIG. 6 is a cross-sectional view of a transistor device according to a fifth embodiment, wherein heavily n-type doped III-nitride regions are formed in ohmic recess regions extending to the channel layer, and the source and drain electrodes are formed in contact with the heavily n-type doped III-nitride regions.

### DETAILED DESCRIPTION OF THE INVENTION

Reference will now be made in detail to the preferred embodiments of the invention, examples of which are illustrated in the accompanying drawings. The same reference numbers are used throughout to refer to the same or like elements.

### I. Overview and Structural Arrangement

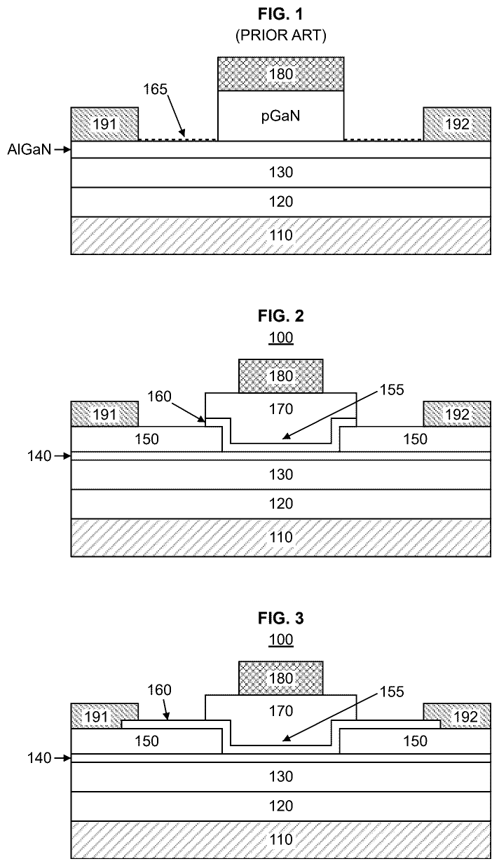

Referring to FIG. 2, a transistor device 100 according to a first embodiment of the invention includes: a substrate 110, a buffer layer 120, a channel layer 130, an etch stop layer 140, a cap layer 150 having a recessed gate region 155, a barrier layer 160 in the recessed gate region, a p-type III-nitride (pGaN) layer 170 over the barrier layer, a gate electrode 180, and source electrode 191 and drain electrode 192 on opposing lateral sides of the gate.

Following cap layer recess, the exposed surface of the etch stop layer 140 in the recessed gate region 155 may optionally be subjected to additional surface treatment, including partial or complete removal of the etch stop layer 140 in the recessed gate region 155, prior to subsequent deposition of the barrier layer 160.

### II. Substrate, Buffer, and Channel Layers

The substrate 110 may comprise silicon (Si), silicon carbide (SiC), sapphire, or other suitable materials. The buffer layer 120 accommodates lattice and thermal mismatch between the substrate 110 and the III-nitride epitaxial layers, and provides electrical isolation. The buffer layer 120 may comprise one or more layers of AlN, AlGaN, or GaN, optionally with compensation doping (e.g., carbon or iron). The channel layer 130 comprises a III-nitride semiconductor, preferably undoped or lightly doped gallium nitride (GaN), over the buffer layer 120. A two-dimensional electron gas (2 DEG) forms at the upper interface of the channel layer 130.

### III. Etch Stop Layer (140)

The etch stop layer 140 is formed over the channel layer 130 and comprises at least one of aluminum nitride (AlN), aluminum gallium nitride (AlGaN), and indium aluminum nitride (InAlN), and may be formed as a single layer or as a combination of sub-layers thereof (e.g., an AlN sub-layer combined with an AlGaN sub-layer), wherein the aluminum composition within any sub-layer may be uniform or continuously graded through its thickness. The material composition is chosen to exhibit higher etch resistance than the cap layer 150, enabling selective removal of the cap layer 150 by dry etching, for example inductively coupled plasma reactive ion etching (ICP-RIE), to form the gate recess region while protecting the underlying structure, and further serving, in certain embodiments, as a defined etch stop for ohmic recess etching at the source and drain electrode locations. The etch stop layer 140 has a total thickness ranging from approximately 0.5 nm to approximately 20 nm, although thicker etch stop layers are not precluded where the epitaxial strain constraints and threshold voltage requirements permit. In addition, the etch stop layer 140 may contribute to the polarization-induced conduction band profile and carrier confinement in the gate region, depending on its composition and thickness.

### IV. Cap Layer (150)

The cap layer 150 is formed over the etch stop layer 140 and comprises a III-nitride semiconductor having a lower aluminum content than the etch stop layer 140, thereby enabling selective dry etching of the cap layer 150 with respect to the etch stop layer 140. In a preferred embodiment, the cap layer 150 comprises GaN. The cap layer 150 has a thickness ranging from approximately 5 nm to over 50 nm, although thicker cap layers are not precluded. The cap layer 150 serves as a protective surface layer in the access regions between the gate electrode and the source and drain electrodes, shielding the etch stop layer 140 and the underlying 2 DEG channel from process-induced damage, environmental degradation, and surface damage caused by subsequent pGaN etching during gate formation. In embodiments where the cap layer 150 is heavily n-type doped, the cap layer 150 further provides a lateral conduction path in parallel with the 2 DEG channel, reducing access region resistance.

In the gate region, the cap layer 150 is selectively recessed by dry etching to form the recessed gate region 155. The higher etch resistance of the etch stop layer 140 relative to the cap layer 150 provides well-controlled and uniform recess depth across the wafer, substantially reducing the etch-damage problem of conventional devices.

In certain embodiments (FIG. 5), the cap layer 150 is n-type doped with silicon (Si) or other suitable n-type dopants, with a doping density ranging from approximately 1×10\hat{ }15 cm\hat{ }−3 to over 1×10\hat{ }20 cm\hat{ }-3. The doping profile may be uniform or non-uniform; in one embodiment the n-type doping is concentrated near the bottom of the cap layer 150, proximate to the etch stop layer 140, to enhance carrier coupling to the 2 DEG channel. In another embodiment, the n-type doping concentration is higher near the top surface of the cap layer 150 to facilitate low-resistance ohmic contact formation when ohmic electrodes are deposited directly on the cap layer 150.

### V. Barrier Layer (160)

The barrier layer 160 is formed over the exposed etch stop layer 140 in the recessed gate region 155 by deposition techniques including, but not limited to, metal-organic chemical vapor deposition (MOCVD), molecular beam epitaxy (MBE), hydride vapor phase epitaxy (HVPE), atomic layer deposition (ALD), or physical vapor deposition (PVD), or combinations thereof. The barrier layer 160 comprises a III-nitride semiconductor (AlN, AlGaN, InAlN, or combinations thereof) with an aluminum content higher than the cap layer 150, typically ranging from approximately 5% to approximately 100% aluminum, with values between approximately 20% and 35% being typical. The barrier layer 160 may be formed as a single compositionally uniform layer, a layer with a graded aluminum composition, or a combination of sub-layers of differing III-nitride compositions, wherein the aluminum composition may vary continuously or in discrete steps through the thickness of the barrier layer 160. The total thickness of the barrier layer 160 ranges from approximately 1 nm to approximately 20 nm, although thicker barrier layers are not precluded where epitaxial strain constraints and threshold voltage requirements permit. The barrier layer 160 and the underlying etch stop layer 140 establish the band structure and polarization conditions in the gate region that support the desired threshold voltage characteristics together with the overlying p-type III-nitride layer 170.

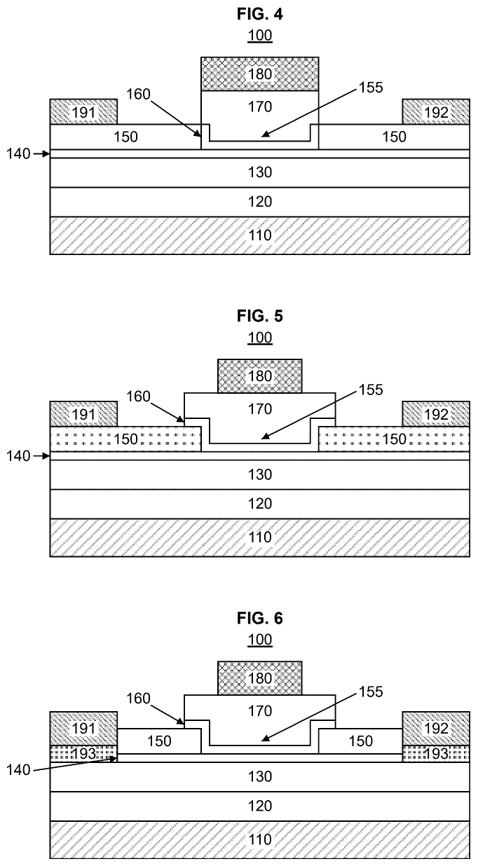

In a preferred embodiment, the barrier layer 160 is formed over the exposed etch stop layer 140 at the bottom of the recessed gate region 155 and on the sidewalls of the cap layer 150 within the recess. In another embodiment, the barrier layer 160 may not extend fully along the sidewalls of the cap layer 150, for example where epitaxial growth conditions favor deposition preferentially on the bottom surface of the recess over the sidewall surfaces. In the embodiment of FIG. 3, the barrier layer 160 further extends over the top surface of the cap layer 150 in access regions outside the gate recess. In the embodiment of FIG. 4, the edges of the barrier layer 160 are flush with the edges of the recess region 155. In a related embodiment, the barrier layer 160 and the p-type III-nitride layer 170 are patterned using a common mask such that their lateral edges are substantially aligned with each other. Variations in lateral etch rate and etch profile may result in edges that are not precisely flush.

### VI. P-type III-nitride Layer (170)

The p-type III-nitride layer 170 comprises a Mg-doped p-type III-nitride semiconductor, preferably GaN, although other III-nitride compositions are not precluded, formed over the barrier layer 160 in the recessed gate region 155, by deposition techniques including but not limited to MOCVD, MBE or HVPE. The p-type III-nitride layer 170 has a thickness ranging from approximately 5 nm to over 100 nm, and a Mg doping density ranging from approximately 1×10\hat{ }17 cm\hat{ }−3 to over 1×10\hat{ }20 cm\hat{ }−3. The p-type III-nitride layer 170 depletes the 2 DEG beneath the gate under zero bias, producing normally-off operation with a positive threshold voltage.

Regarding the relationship between the p-type III-nitride layer 170 and the barrier layer 160: in one embodiment, both layers are removed using a common mask such that their lateral edges are substantially aligned with each other. In another embodiment, only the p-type III-nitride layer 170 is removed while the barrier layer 160 is retained over at least a portion of the access regions, wherein the cap layer 150 beneath the retained barrier layer 160 shields the 2 DEG channel from surface damage. In practice, removal of the p-type III-nitride layer 170 may result in partial etching into the barrier layer 160, and removal of both the p-type III-nitride layer 170 and the barrier layer 160 may result in partial etching into the cap layer 150, due to etch selectivity limitations and process variation.

Regarding the relationship between the patterned gate stack and the gate recess edges: in one embodiment, the lateral edges of the p-type III-nitride layer 170 and the barrier layer 160 are substantially aligned with the edges of the recessed gate region 155. In another embodiment, the lateral edges of the p-type III-nitride layer 170 and the barrier layer 160 extend beyond the gate recess edges onto the cap layer 150 in the access regions. The term “substantially aligned” as used herein accommodates minor lateral offsets arising from process variation.

The Mg doping profile may be non-uniform, with higher Mg concentration in a central region or at the surface of the p-type III-nitride layer 170, to optimize depletion characteristics and threshold voltage.

### VII. Gate Electrode (180), Source and Drain Electrodes (191, 192)

The gate electrode 180 is formed over and in contact with the p-type III-nitride layer 170, comprising one or more conductive materials selected from the group consisting of Ti, TiN, Al, Ni, W, Au, Cu, and Pt. As shown in FIGS. 2 and 3, the gate electrode 180 footprint may be narrower than the p-type III-nitride layer 170. As shown in FIG. 4, the gate electrode 180 footprint may be substantially flush with the p-type III-nitride layer 170 edges.

The source electrode 191 and drain electrode 192 are formed on opposing sides of the gate region and make ohmic contact to the semiconductor material in the ohmic contact regions, comprising Ti, Al, W, TiN, Au, Cu, or other suitable conductive materials. The source and drain electrodes may be formed in ohmic recess regions, in which material has been selectively removed to a depth selected from the group consisting of: partially into or through any remaining barrier layer 160, partially into the cap layer 150, through the cap layer 150 to a surface of the etch stop layer 140, partially into the etch stop layer 140, and through the etch stop layer 140 into the channel layer 130. The source and drain electrodes are deposited in the ohmic recess regions in contact with one of the barrier layer 160, the cap layer 150, the etch stop layer 140, or the channel layer 130, depending on the recess depth. In one embodiment, where the p-type III-nitride layer 170 and the barrier layer 160 have been removed from the ohmic recess regions, the ohmic contacts are deposited directly on the surface of the cap layer 150, which in heavily n-type doped embodiments provides low contact resistance without further recess etching. Where a barrier layer 160 remains on the surface of the access regions after p-type III-nitride removal, the ohmic recess etches through the remaining barrier layer 160 before reaching the cap layer 150 or deeper layers. In a further embodiment, at least one of the source and drain electrodes contacts a p-type III-nitride region that is electrically isolated from the gate electrode and from the p-type III-nitride layer 170 beneath the gate electrode. The isolated p-type III-nitride region may be formed during the same deposition step as the p-type III-nitride layer 170 and subsequently patterned to be physically separated from the gate p-type III-nitride layer 170.

The regions 193 may comprise GaN, InGaN, or other suitable III-nitride compositions doped with silicon at a density exceeding approximately 1×10\hat{ }19 cm\hat{ }−3. The regions 193 may be formed by selective-area epitaxial regrowth of doped III-nitride material, or by ion implantation into existing III-nitride material, and may be located on or in the channel layer 130, on or in the etch stop layer 140, or on or in the cap layer 150, depending on the ohmic recess depth. The source electrode 191 and drain electrode 192 are deposited over the regions 193.

The transistor device may additionally incorporate features known in the art, including but not limited to passivation layers, field plates, surface treatment layers, and inter-metal dielectrics, which are compatible with and do not limit the scope of the present invention.

### VIII. Device Operation and Advantages

The etch stop layer 140 provides controlled, uniform gate recess etching by virtue of its higher etch resistance relative to the cap layer 150, significantly reducing recess depth variability across the wafer. The cap layer 150 shields the underlying etch stop layer 140 and the 2 DEG channel from process-induced surface damage regardless of whether the p-type III-nitride layer 170 alone or both the p-type III-nitride layer 170 and the barrier layer 160 are subsequently removed from the access regions. The etch stop layer 140 further enables well-controlled ohmic recess etching by providing defined etch stop points at multiple depths within the layer stack, and in embodiments where the cap layer 150 is heavily n-type doped, ohmic contacts may be formed directly on the cap layer 150 with low contact resistance. In embodiments where the barrier layer 160 and p-type III-nitride layer 170 extend beyond the gate recess region onto the cap layer 150, the resulting gate stack geometry facilitates gate electrode formation at reduced gate lengths and may provide additional electric field management in the access regions.

Unlike prior art approaches that each address only a subset of the foregoing limitations, the present invention resolves the threshold voltage-access resistance trade-off, process-induced surface damage, and ohmic contact variability within a single unified device architecture. The transistor device may be configured for enhancement-mode (normally-off) operation with a positive threshold voltage, or for depletion-mode (normally-on) operation with a negative threshold voltage, depending on layer compositions and thicknesses.

What is claimed is:

1. A transistor device comprising:
a substrate;
a buffer layer over the substrate;
a channel layer comprising a III-nitride semiconductor material formed over the buffer layer;
an etch stop layer formed over the channel layer, the etch stop layer comprising a material selected from the group consisting of aluminum nitride (AlN), aluminum gallium nitride (AlGaN), indium aluminum nitride (InAlN), and combinations thereof;
a cap layer formed over the etch stop layer, the cap layer comprising a III-nitride semiconductor material having a lower aluminum content than the etch stop layer, wherein the cap layer has a recessed gate region in which the cap layer is removed to expose the etch stop layer;
a barrier layer formed at least in the recessed gate region over the etch stop layer, the barrier layer comprising a III-nitride semiconductor material having a higher aluminum content than the cap layer;
a p-type III-nitride layer formed at least in the recessed gate region over the barrier layer;
a gate electrode formed over the p-type III-nitride layer; and
source and drain electrodes formed on opposing lateral sides of the gate electrode.

2. The transistor device of claim 1, wherein the etch stop layer comprises a combination of an AlN sub-layer and an AlGaN sub-layer, and wherein the etch stop layer has a total thickness ranging from approximately 0.5 nm to approximately 20 nm.

3. The transistor device of claim 1, wherein the cap layer comprises gallium nitride (GaN) and has a total thickness ranging from approximately 5 nm to over 50 nm.

4. The transistor device of claim 1, wherein the barrier layer has an aluminum percentage ranging from approximately 5% to approximately 100%, and a total thickness ranging from approximately 1 nm to over 20 nm.

5. The transistor device of claim 1, wherein the p-type III-nitride layer comprises Mg-doped p-type gallium nitride having a total thickness ranging from approximately 5 nm to over 100 nm and an Mg doping density ranging from approximately 1×10\hat{ }17 cm\hat{ }−3 to over 1×10\hat{ }20 cm\hat{ }−3.

6. The transistor device of claim 1, wherein the barrier layer is formed over the exposed etch stop layer at the bottom of the recessed gate region and on sidewalls of the cap layer within the recessed gate region.

7. The transistor device of claim 1, wherein the barrier layer extends laterally beyond the recessed gate region.

8. The transistor device of claim 7, wherein lateral edges of the barrier layer extend further from the recessed gate region than lateral edges of the p-type III-nitride layer.

9. The transistor device of claim 1, wherein the p-type III-nitride layer extends laterally beyond the recessed gate region.

10. The transistor device of claim 1, wherein lateral edges of the p-type III-nitride layer and lateral edges of the barrier layer are substantially aligned with each other.

11. The transistor device of claim 1, wherein the cap layer is n-type doped at a doping density ranging from approximately 1×10\hat{ }15 cm\hat{ }−3 to over 1×10\hat{ }20 cm\hat{ }−3, wherein the doping profile is uniform or non-uniform through the cap layer.

12. The transistor device of claim 1, further comprising ohmic recess regions at the source and drain electrodes, wherein each ohmic recess region extends from a topmost layer present at a respective ohmic recess location to a selected recess depth, wherein a bottom surface of each ohmic recess region is located on or within a layer selected from the group consisting of: the barrier layer, the cap layer, the etch stop layer, and the channel layer; and wherein the source and drain electrodes are formed in the ohmic recess regions.

13. The transistor device of claim 12, wherein the bottom surface of each ohmic recess region is located on or within the cap layer, and wherein the source and drain electrodes are formed in contact with the cap layer in the ohmic recess regions.

14. The transistor device of claim 12, wherein heavily n-type doped III-nitride regions having a silicon doping density exceeding approximately 1×10\hat{ }19 cm\hat{ }−3 are formed in the ohmic recess regions, and wherein the source and drain electrodes are formed in contact with the heavily n-type doped III-nitride regions.

15. The transistor device of claim 1, wherein the transistor device is configured to operate in an enhancement mode having a positive threshold voltage.

16. A method of fabricating a transistor device, comprising:
forming a buffer layer over a substrate;
forming a channel layer comprising a III-nitride semiconductor material over the buffer layer;
forming an etch stop layer over the channel layer, the etch stop layer comprising a material selected from the group consisting of aluminum nitride (AlN), aluminum gallium nitride (AlGaN), indium aluminum nitride (InAlN), and combinations thereof;
forming a cap layer over the etch stop layer, the cap layer comprising a III-nitride semiconductor material having a lower aluminum content than the etch stop layer;
selectively removing the cap layer in a gate region to form a recessed gate region that exposes the etch stop layer while preserving the cap layer in regions adjacent to the gate region;
forming a barrier layer at least in the recessed gate region over the exposed etch stop layer, the barrier layer comprising a III-nitride semiconductor material having a higher aluminum content than the cap layer;
forming a p-type III-nitride layer at least in the recessed gate region over the barrier layer;
forming a gate electrode over the p-type III-nitride layer; and
forming source and drain electrodes on opposing lateral sides of the gate electrode.

17. The method of claim 16, further comprising:
removing the p-type III-nitride layer from at least a portion of an area outside the recessed gate region;
forming ohmic recess regions at the source and drain electrode locations by etching from a topmost layer present at a respective ohmic recess location to a selected recess depth, wherein a bottom surface of each ohmic recess region is located on or within a layer selected from the group consisting of: the barrier layer, the cap layer, the etch stop layer, and the channel layer;
wherein the source and drain electrodes are formed in the ohmic recess regions.

18. The method of claim 17, further comprising removing the barrier layer from at least a portion of the area outside the recessed gate region.

19. The method of claim 16, further comprising n-type doping the cap layer during growth to a doping density ranging from approximately 1×10\hat{ }15 cm\hat{ }−3 to over 1×10\hat{ }20 cm\hat{ }−3, wherein the doping profile is uniform or non-uniform through the cap layer.

20. The method of claim 17, further comprising:
forming heavily n-type doped III-nitride regions in the ohmic recess regions prior to forming the source and drain electrodes, the heavily n-type doped III-nitride regions having a silicon doping density exceeding approximately 1×10\hat{ }19 cm\hat{ }−3; and
forming the source and drain electrodes in contact with the heavily n-type doped III-nitride regions.
